(19) United States
(12) Patent Application Publication
(10) Pub. No.: US 2009/0092754 A1
(43) Pub. Date: Apr. 9, 2009

(54) FILM FORMATION METHOD, MASK FOR FILM FORMATION AND FILM FORMATION DEVICE

(76) Inventor: Masahiro Watabe, Miyazaki (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/064,819

(22) PCT Filed: Aug. 26, 2005
(86) PCT No.: PCT/JP2005/015514

§ 371 Date: Dec. 9, 2008

(51) Int. Cl. C23C 16/04; B05B 15/04

(52) U.S. Cl. 427/255.28; 118/720; 118/504

(57) ABSTRACT

A film formation method is provided for masking a part of a surface of an object and subsequently forming a film, by a chemical vapor deposition method, on a surface on which a film should be formed that is an exposed part of the surface of the object. The film formation method includes, upon film formation in a reaction chamber, masking the object by using a mask having a gas path formed therewithin and vents connecting the gas path with an outer surface of the mask, and controlling concentration distribution of raw material substances in the reaction chamber so that a film formation rate in the surface on which a film should be formed is constant by discharging or attenuating raw material gases, using the gas path within the mask, supplied to a surface which is covered with the mask and on which no film is formed.

### TECHNICAL FIELD

The present invention relates to a method for forming a film by a Chemical Vapor Deposition (CVD) method and a mask used for a masking step in film formation.

### BACKGROUND ART

The Chemical Vapor Deposition method is a method for forming a film by using raw material gases by a chemical reaction. This method has a wide range of industrial applications from thin film formation in microdevices such as a semiconductor device to coating on objects having a length greater than 1 m.

The Chemical Vapor Deposition method has recently been also used for manufacturing display panels having a large screen with a diagonal size equal to or more than 1 m. U.S. Pat. No. 6,450,849 describes a method for manufacturing an AC plasma display panel in which a dielectric layer for covering electrodes is formed by a plasma CVD method. The Chemical Vapor Deposition method makes it possible to obtain a dielectric layer having a small and uniform thickness. Compared to a thick film method, the Chemical Vapor Deposition method can form, at a low temperature, a dielectric layer made of, for example, silicon dioxide or organic silicon oxide having a dielectric constant lower than that of a low-melting point glass that is a general material.

In general, a film formation device used for forming a film by the Chemical Vapor Deposition method is designed to supply raw material substances equally to a surface on which a film should be formed. For example, Japanese unexamined patent publication No. 11-350143 describes a parallel plate plasma CVD system. In the system, a shower plate whose thickness is purposely uneven is disposed between a gas inlet port of a reaction chamber and a surface on which a film should be formed. The shower plate is a nozzle that injects a gas to the entire surface on which a film should be formed and has many micro injection holes. The shower plate uses the fact that a gas flow rate of an injection hole depends on the length of the injection hole. Then, thicknesses of the shower plate at various positions are so selected that a gas injection rate at the center of the shower plate is equal to a gas injection rate in ends of the shower plate.

For film formation by the Chemical Vapor Deposition method, in the case where an object on which a film should be formed has a part on which film formation is unnecessary, masking is performed on the part. Japanese unexamined patent publication No. 11-269646 discloses a technique of performing masking using a jig having a coefficient of thermal expansion that is substantially the same as that of an object on which a film should be formed.

### DISCLOSURE OF THE INVENTION

In the manufacture of a plasma display panel in which the Chemical Vapor Deposition method is used to form a dielectric layer on a substrate in which electrodes are arranged, unfortunately, a thickness of a dielectric layer becomes uneven when masking is performed with the substrate being covered with a mask in order to expose terminal portions of the electrodes. Specifically, such masking causes the vicinity of the mask to be thicker than the other parts.

The uneven thickness of the dielectric layer causes variations in operating characteristics of cells constituting a screen. It is desirable that the thickness of the dielectric layer be uniform for high-quality display in a stable manner.

The present disclosure is directed to solve the problems pointed out above, and therefore, an object of an embodiment of the present invention is to provide a uniform film thickness in film formation including a masking step.

According to one aspect of the present invention, a film formation method for masking a part of a surface of an object and subsequently forming a film, by a chemical vapor deposition method, on an exposed part without any mask of the surface of the object, the film formation method includes masking the object by using a mask when film formation is performed in a reaction chamber, the mask having a gas path formed within the mask and vents connecting the gas path with an outer surface of the mask, and controlling concentration distribution of raw material substances in the reaction chamber so that a film formation rate in the surface on which a film should be formed is constant by discharging or attenuating raw material gases, using the gas path within the mask, supplied to a surface which is covered with the mask and on which no film is formed.

These and other characteristics and objects of the present invention will become more apparent by the following descriptions of preferred embodiments with reference to drawings.

### BRIEF DESCRIPTION OF THE DRAWINGS

FIG. 1 is an exploded perspective view showing an example of a cell structure of a plasma display panel.

FIG. 2 is a plan view showing a pattern of display electrodes.

FIG. 3 is a diagram showing an area where masking is necessary when a dielectric layer is formed in the manufacture of a plasma display panel.

FIG. 4 is a plan view showing a mask used in the manufacture of a plasma display panel.

FIG. 5 is a sectional diagram taken along the line a-a of FIG. 4.

FIG. 6 is a schematic diagram showing the outline of a film formation device according to a first embodiment.

FIG. 7 is a plan view showing another example of a mask used in the manufacture of a plasma display panel.

FIG. 8 is a schematic diagram showing the outline of a film formation device according to a second embodiment.

### BEST MODE FOR CARRYING OUT THE INVENTION

The following is a description of a film formation method according to the present invention. In the description, formation of a dielectric layer of a plasma display panel is exemplified.

### First Embodiment

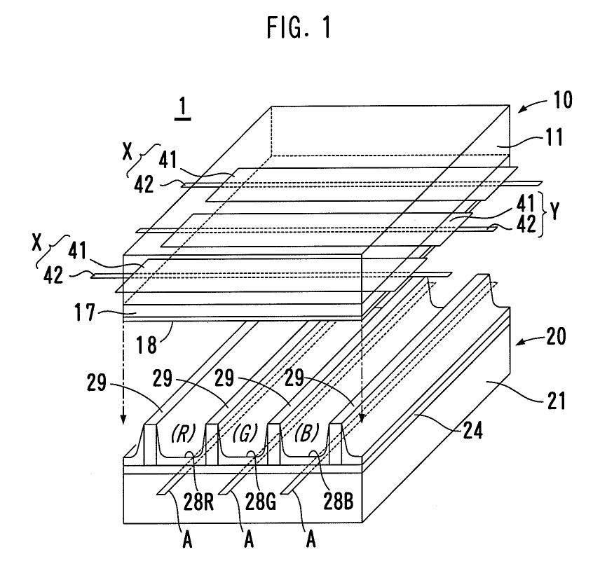

FIG. 1 is an exploded perspective view showing an example of a cell structure of a plasma display panel. Referring to FIG. 1, a front panel 10 and a rear panel 20 are separated from each other for easy understanding of the inside structure of the plasma display panel.

The plasma display panel 1 is made up of the front panel 10 and the rear panel 20. The front panel 10 includes a glass substrate 11, display electrodes X and Y, a dielectric layer 17 and a protection film 18. Each of the display electrodes X and Y is a laminate including a patterned transparent conductive film 41 and a patterned metal film 42. The display electrodes X and Y are covered with the dielectric layer 17 and the protection film 18. The rear panel 20 includes a glass substrate 21, address electrodes A, an insulation layer 24, a plurality of partitions 29 and fluorescent material layers 28R, 28G and 28B. The illustrated arrangement pattern of the partitions 29 is a stripe pattern. Each of the alphabets R, G and B in parentheses shown in the drawing represents a light emission color of a fluorescent material.

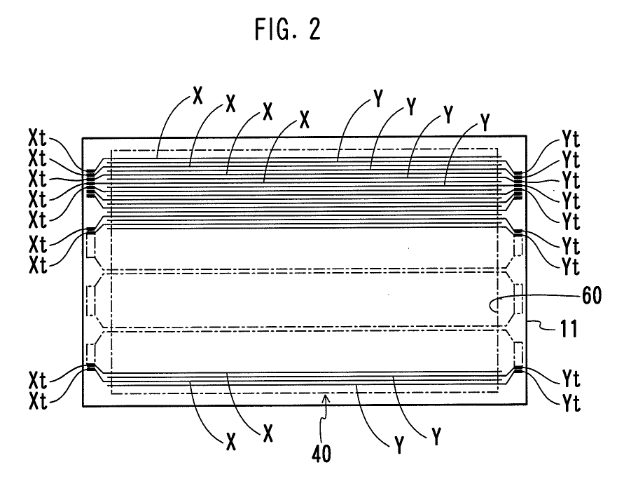

FIG. 2 is a pattern of the display electrodes. The display electrodes X and the display electrodes Y that make an electrode group 40 are extended from a screen 60 to a vicinity of a periphery of the glass substrate 11. Each of the display electrodes X and Y has on its end a terminal Xₜ or Yₜ for conductive connection to a drive unit. Referring to FIG. 2, the terminals Xₜ of the respective display electrodes X are disposed on the left side of the glass substrate 11 while the terminals Yₜ of the respective display electrodes Y are disposed on the right side thereof. The arrangement pitch of the terminals Xₜ is different from that of the display electrodes X in the screen 60; therefore the left end portions including the terminals Xₜ of the display electrodes X are patterned to have a bent ribbon-like shape. The bent portions are made up of only the metal film 42 rather than the laminate of the transparent conductive film 41 and the metal film 42. Likewise, the right end portions including the terminals Yₜ of the display electrodes Y are patterned to have a bent ribbon-like shape. The bent portions are made up of only the metal film 42.

The plasma display panel 1 of this type is manufactured by making the front panel 10 and the rear panel 20 separately, and then, bonding the front panel 10 and the rear panel 20 together. A mother glass substrate whose area is twice or more as large as the glass substrate 11 is used to make a plurality of the front panels 10 at one time. A plurality of the rear panels 20 is formed at one time in the same manner. Before bonding the front panel 10 and the rear panel 20 together, a mother glass substrate is divided into a plurality of the front panels 10 or a plurality of the rear panels 20. Then, the front panel 10 separated from a mother glass substrate is bonded to the rear panel 20 separated from a mother glass substrate, so that the front panel 10 and the rear panel 20 are integrated with each other. Upon making the front panel 10, the dielectric layer 17 is formed by a Chemical Vapor Deposition method. During this process, masking is performed on the terminals Xₜ and Yₜ.

If no masking is performed, it is necessary, after forming the dielectric layer 17, to remove a part of the dielectric layer 17 by etching or grinding and to expose the terminals Xₜ and Yₜ. The masking step eliminates the need for the step of removing the dielectric layer 17. This shortens manufacturing time, increases a yield, and improves productivity.

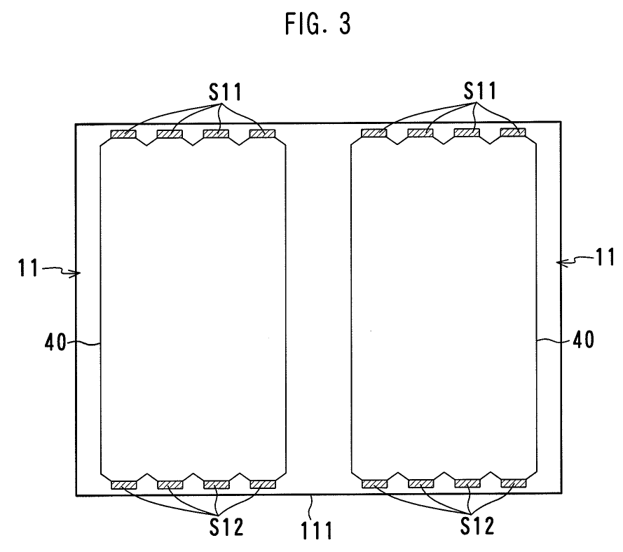

FIG. 3 is a diagram showing an area where masking is necessary when a dielectric layer is formed in the manufacture of a plasma display panel.

Referring to FIG. 3, two electrode groups 40 are formed on a mother glass substrate 111 in the form of two lines. A section of the mother glass substrate 111 in which one of the two electrode groups 40 is placed corresponds to the glass substrate 11 on the front side of one plasma display panel. Areas of the mother glass substrate 111 where masking is necessary are areas S11 corresponding to terminals of the electrode groups 40 shown in the upper part of the drawing and areas S12 corresponding to terminals of the electrode groups 40 shown in the lower part of the drawing.

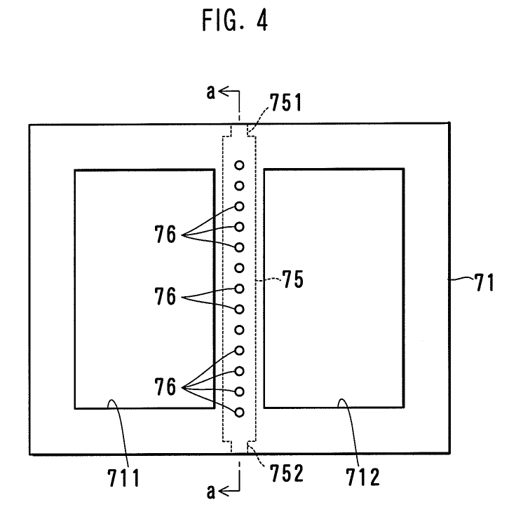

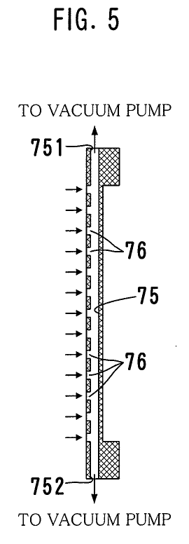

FIG. 4 is a plan view showing a mask used in the manufacture of a plasma display panel, and FIG. 5 is a sectional diagram taken along the line a-a of FIG. 4.

A mask 71 is a frame-like member made of aluminum having a thickness of approximately 30 mm. The mask 71 has two rectangular openings 711 and 712 necessary to form dielectric layers for two plasma display panels at one time. The mask 71 has a contour and a thickness greater than those of the mother glass substrate. Accordingly, the mask 71 has sufficient mechanical strength to function as a pressing member for preventing the mother glass substrate from warping due to heating.

A peripheral surface of each of the openings 711 and 712 is formed to have a tapered shape in which an upper part of the opening is broadened, which avoids generating a part where nothing is deposited. A step portion is formed around the opening in order that a lower end of the peripheral surface is away from the upper surface of the electrode group 40 by approximately 0.5 mm to 1.0 mm. The step portion causes the mother glass substrate and the mask to be in a non-contact state, thereby preventing the terminals and terminal lead-out portions (bent portions of the ends of the display electrodes) from being scratched.

The mask 71 has, as elements unique to the present invention, a gas path 75 and a plurality of vents 76. The gas path 75 and the vents 76 are provided in an area between the openings 711 and 712.

As shown in FIG. 5, the gas path 75 is formed within the mask 71 and has a length over the entire length of the opening 711 or 712 in the longitudinal direction. End portions 751 and 752 of the gas path 75 communicate with the outer peripheral surface of the mask 71, so that the end portions 751 and 752 can connect to piping of an exhaust system (not shown).

The vents 76 are arranged at almost regular intervals in the form of one line along the gas path 75. Each of the vents 76 communicates with the gas path 75 and the front face of the mask 71 as shown in FIG. 5.

Examples of a method for making the mask 71 are a method of forming the gas path 75 and the vents 76 by a machining process and a method of making parts of the mask 71 separately and combining the resultant parts to form the gas path 75 as a groove.

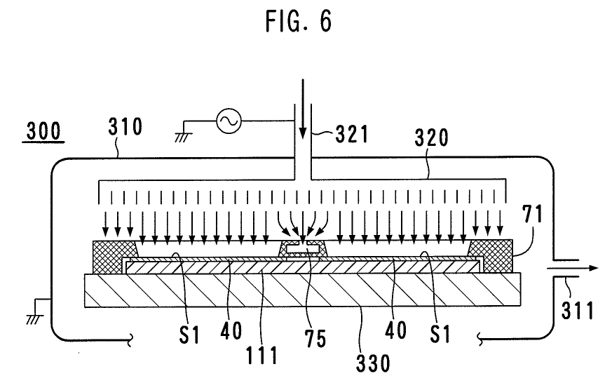

FIG. 6 is a schematic diagram showing the outline of a device used for forming a dielectric layer by a Chemical Vapor Deposition method.

A parallel plate plasma CVD system 300 is used for forming a dielectric layer (hereinafter referred to as film formation). The plasma CVD system 300 includes a reaction chamber 310 that is a container made of metal, a shower nozzle 320 functioning also as an electrode for generating plasma, a movable base 330 for supporting an object on which a film should be formed and the mask 71 for masking as described above. The movable base 330 has a heater, incorporated therein, for heating the object.

The mask 71 is placed between the shower nozzle 320 and the movable base 330 within the chamber 310. The gap size between the mask 71 and the shower nozzle 320 is approximately 10 mm to 20 mm. In the illustrated example, the mother glass substrate 111 in which the electrode groups 40 are formed is placed on the movable base 330 and the mother glass substrate 111 is covered with the mask 71.

In this example, the movable base 330 is of a lift type capable of moving in the vertical direction. When the mother glass substrate 111 is brought in or carried out, the movable base 330 goes down and is distanced from the mask 71 fixedly placed.

The following is a description of the outline of a film formation process.

Raw material gases are provided from an inlet port 321 formed at the center of the shower nozzle 320 to the chamber 310 in the state in which the internal pressure of the chamber 310 in which the mother glass substrate 111 is brought is reduced to a pressure of, for example, approximately 2.5 Torr to 3.5 Torr and the mother glass substrate 111 is heated up to a temperature of approximately 200° C. to 400° C. In the case where a dielectric layer made of silicon dioxide is formed, for example, silane (SiH₄) is provided as a source gas and, for example, nitrous oxide (N₂O) is provided as a reaction gas. The raw material gases thus provided are injected from the shower nozzle 310 to the entire mother glass substrate 111 substantially uniformly.

The chamber 310 is exhausted through a main exhaust hole 311, concomitantly with the provision of the raw material gases. The chamber 310 is provided with a vacuum gauge (not shown). A valve of the exhaust system is controlled in accordance with the output of the vacuum gauge; thereby a vacuum level of the chamber 310 is maintained at a constant level.

In the chamber 310 to which a constant amount of the raw material gases is supplied as described above, plasma generated by applying a high-frequency power activates the raw material gases, leading to the promotion of a chemical reaction. Then, raw material substances generated by the chemical reaction deposit on a surface S1 on which a film should be formed of the mother glass substrate 111, so that a film, which eventually becomes a dielectric layer, is formed. The surface S1 in this example is a non-masked portion of the upper surface of the mother glass substrate 111 in which the electrode groups 40 are formed. In a precise sense, the surface S1 is made up of exposure surfaces of the electrode groups 40 and a substrate surface between the electrodes.

In the first embodiment, while such film formation is performed, a gas within the chamber 310 is continuously or intermittently sucked into the gas path 75 within the mask 71. Specifically, the exhaust system connected to the end portions 751 and 752 (see FIG. 5) of the gas path 75 is used to increase the vacuum level of the gas path 75 compared to the vacuum level outside the mask 71.

The exhaust system used for the suction may be of a type that uses a vacuum pump of an exhaust system for suction from the main exhaust hole 311 or of a type that has a special vacuum pump. In the case of using the vacuum pump of the exhaust system for suction from the main exhaust hole 311, a special valve is provided for independently adjusting an amount of gas to be sucked into the gas path 75.

The gas sucked into the gas path 75 contains unreacted raw material gases and raw material substances that are generated by a chemical reaction and do not deposit.

The suction of gas into the gas path 75 contributes to achievement of uniform thickness of a film formed on the surface S1. The following is a reason why uniform thickness of a film is achieved. Few raw material substances deposit on the mask 71. Stated differently, compared to the film formation rate in the surface S1, the film formation rate in the mask surface is very low. Unless the suction is performed, raw material gases injected by the shower nozzle 320 to the mask 71 and raw material substances generated between the shower nozzle 320 and the mask 71 flow to the surface S1. Consequently, the concentration of the raw material substances are locally increased at a portion of the surface S1 close to the mask 71 and the film formation rate in the portion is higher than that of the other portions of the surface S1. The appropriate suction of gas into the gas path 75 reduces or eliminates the excess supply of gas from a space between the shower nozzle 320 and the mask 71 to a space between the shower nozzle 320 and the surface S1, thereby making it possible to equalize the film formation rate in the surface S1.

In the plasma CVD system 300 according to this embodiment, the mask 71 is placed just below a position at which the inlet port 321 of the shower nozzle 320 is provided. At the position, the injection amount of the raw material gases tends to be large compared to that at the other positions of the shower nozzle 320. Accordingly, it is effective in equalizing a thickness of a film to be formed to suck the raw material gases into the mask 71 just below the position.

### Second Embodiment

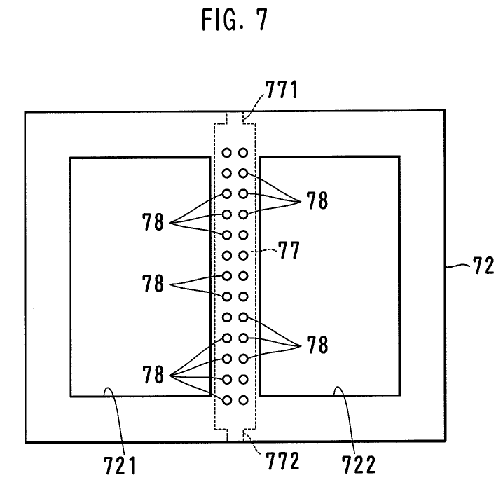

FIG. 7 is a plan view showing another example of the mask used in the manufacture of a plasma display panel.

The basic structure of a mask 72 shown in FIG. 7 is the same as that of the mask 71 described earlier with reference to FIG. 4. Similarly to the mask 71, the mask 72 also has two rectangular openings 721 and 722 necessary to form dielectric layers for two plasma display panels at one time.

The mask 72 has, as elements unique to the present invention, a gas path 77 and a plurality of vents 78. The gas path 77 and the vents 78 are provided in an area between the openings 721 and 722.

The gas path 77 is formed within the mask 72 and has a length over the entire length of the opening 721 or 722 in the longitudinal direction. End portions 771 and 772 of the gas path 77 communicate with the outer peripheral surface of the mask 72, so that the end portions 771 and 772 can connect to piping of a gas supply system (not shown).

The vents 78 are arranged at almost regular intervals in the form of two lines along the gas path 77. Each of the vents 78 communicates with the gas path 77 and the front face of the mask 72.

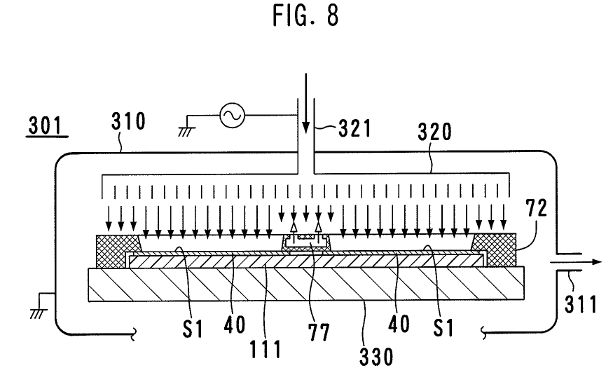

FIG. 8 is a schematic diagram showing the outline of a film formation device according to the second embodiment. In FIG. 8, similar reference numerals are used to denote elements similar to those of the device shown in FIG. 6. Description of these elements is omitted.

A plasma CVD system 301 shown in FIG. 8 has the same structure as that of the plasma CVD system 300 shown in FIG. 6 except in that the plasma CVD system 301 includes a mask 72 instead of the mask 71 in the plasma CVD system 300.

In the second embodiment, while the plasma CVD system 301 is used to form a film, inert gases are continuously or intermittently provided to the chamber 310 through the gas path 77 and the vents 78, concomitantly with the provision of the raw material gases. Argon (Ar) and nitrogen (N₂) are suitable inert gases.

Providing the inert gases from the gas path 77 has an effect of attenuating the raw material gases locally in the vicinity of the mask 72. Providing the inert gases appropriately reduces or eliminates the local increase in the concentration of raw material substances, which occurs at a part close to the mask 72, thereby making it possible to equalize the film formation rate in the surface S1.

In the first and second embodiments described above, the cases in which the vents 76 or 78 are formed only in an area between the two openings of the mask 71 or 72 are exemplified. The present invention, however, is not limited to the cases. The vents 76 or 78 may be formed at a part necessary to equalize the film thickness depending on the structure of a film formation device. For example, in the case of a film formation device configured to supply raw material gases equally to the entire surface of an object on which a film should be formed, a gas path passing through the entire periphery of an opening of a mask is formed and vents are arranged along the entire periphery of the opening.

Either one or both of the size and density of the vents 76 or 78 may be optimized depending on the positions where the vents 76 or 78 are arranged. Stated differently, the present invention does not exclude a case in which the size and density of the vents 76 or 78 are different.

The shape, size, thickness, and material of each of the masks 71 and 72 should be selected depending on purposes and can be changed appropriately. In the case where, for example, film formation is performed for four, eight or more plasma display panels at one time, a mask having an appropriate size is used.

The present invention can be applied to film formation by not only a Chemical Vapor Deposition method such as a plasma CVD method but also a Chemical Vapor Deposition method such as a thermal CVD method or an optical CVD method.

### INDUSTRIAL APPLICABILITY

The present invention can be applied to film formation in which a mask having a size large enough to form a gas path therewithin is used. The present invention can be used for manufacturing, for example, a flat panel display such as a plasma display panel and a liquid crystal panel.

1. A film formation method for masking a part of a surface of an object and subsequently forming a film, by a chemical vapor deposition method, on an exposed part without any mask of the surface of the object, the film formation method comprising:
masking the object by using a mask when film formation is performed in a reaction chamber, the mask having a gas path formed within the mask and vents connecting the gas path with an outer surface of the mask; and
controlling concentration distribution of raw material substances in the reaction chamber by using the gas path.

2. A film formation method for masking a part of a surface of an object and subsequently forming a film, by a chemical vapor deposition method, on an exposed part without any mask of the surface of the object, the film formation method comprising:
masking the object by using a mask when film formation is performed in a reaction chamber, the mask having a gas path formed within the mask and vents connecting the gas path with an outer surface of the mask; and
during performing the film formation, sucking a gas in the reaction chamber from the vents into the gas path.

3. A film formation method for masking a part of a surface of an object and forming a film, by a chemical vapor deposition method, on a part exposed by masking the part of the surface of the object, the film formation method comprising:
masking the object by using a mask when film formation is performed in a reaction chamber, the mask having a gas path formed within the mask and vents connecting the gas path with an outer surface of the mask; and
during performing the film formation, providing an inert gas to the reaction chamber through the gas path and the vents, concomitantly with providing a raw material gas to the reaction chamber.

4. A mask used for a masking step in film formation by a chemical vapor deposition method, the mask comprising:
a gas path formed within the mask; and
vents connecting the gas path with an outer surface of the mask.

5. A film formation device for performing film formation by a chemical vapor deposition method, the device comprising a mask having a gas path formed within the mask and vents connecting the gas path with an outer surface of the mask.
